(19) United States
(12) Patent Application Publication
(10) Pub. No.: US 2026/0060070 A1
(43) Pub. Date: Feb. 26, 2026

(54) THERMAL INTERFACE MATERIAL UNIFORMITY SYSTEM AND METHOD OF OPERATION THEREOF

(71) Applicant: Astera Labs, Inc., Santa Clara, CA (US)

(72) Inventors: Zunhang Yu KASNAVI, Saratoga, CA (US); Girish VIJAYAKUMAR, San Jose, CA (US); Geoffrey CHANG, San Jose, CA (US); Nathaniel UNGER, San Jose, CA (US)

(21) Appl. No.: 19/047,577

(22) Filed: Feb. 6, 2025

Related U.S. Application Data
(60) Provisional application No. 63/687,286, filed on Aug. 26, 2024.

(51) Int. Cl. H01L 23/34

(52) U.S. Cl. CPC H01L 23/34

(57) ABSTRACT

An electronic system for evaluating temperature differences between different pairs of thermal diodes to evaluate the quality of a thermal interface material layer used for cooling the electronic system. Formation of a thermal diode array on a semiconductor die allows the measurement of temperature and temperature differences between a plurality of the thermal diode pairs arranged in an orthogonal configuration. The temperature differences between the thermal diode pairs can indicate the presence of irregular distribution of the thermal interface material. Such components with thermal interface material flaws can be rejected during manufacture to improve manufacturing quality.

### CROSS-REFERENCE TO RELATED APPLICATIONS

This application claims the benefit of U.S. Provisional Patent Application Ser. No. 63/687,286 filed Aug. 27, 2024, the entire contents of the aforementioned are hereby incorporated by reference as if fully set forth herein, under 35 U.S.C. § 120. The applicant(s) hereby rescind any disclaimer of claim scope in the parent application(s) or the prosecution history thereof and advise the USPTO that the claims in this application may be broader than any claim in the parent application(s)

### TECHNICAL FIELD

Embodiments relate generally to electronic manufacturing system quality and performance, and, more specifically, to improve the yield and reliability characteristics for electronic systems by measuring the thermal parameters of electronic structure indicating the uniformity of a thermal interface material layer on semiconductor devices.

### BACKGROUND OF THE INVENTION

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

Semiconductor devices generate heat during operation. High performance and high-speed devices can cause significant heat capable of damaging the devices themselves. Such devices can have elements for dispersing and radiating away the generated heat using heat transfer subsystems such as heat sinks, radiators, cooling systems, and other similar mechanisms.

The semiconductor devices can be formed to discharge heat energy or cool the devices using different techniques. Active and passive cooling systems may be attached to the semiconductor devices to prevent heat damage to the devices. Maintaining the device operation within an optimal operating temperature range and reducing the development of hot spots can ensure system RAS (Reliability, Availability and Serviceability) and long-term reliability of the devices.

### BRIEF DESCRIPTION OF DRAWINGS

The present invention is illustrated by way of example, and not by way of limitation, in the figures of the accompanying drawings and in which like reference numerals refer to similar elements and in which:

FIG. 1 illustrates an example embodiment of an electronic system with a thermal management system,

FIG. 2 illustrates a side view of an example embodiment of an electronic system with a thermal management system,

FIG. 3 illustrates an example embodiment of an electronic system with a thermal management system,

FIG. 4 illustrates an example embodiment of an electronic system with a thermal management system,

FIG. 5 illustrates an example embodiment of an electronic system with a thermal management system,

FIG. 6 illustrates an example embodiment of the thermal management system,

FIG. 7 illustrates a thermal image of an example embodiment of an electronic system with a thermal management system,

FIG. 8 illustrates an example embodiment of an electronic system with a thermal management system,

FIG. 9 illustrates an example embodiment of an electronic system with a thermal management system,

FIG. 10 illustrates an example embodiment of a thermal diode array for an electronic system with a thermal management system,

FIG. 11 illustrates an example embodiment of a thermal interface material layer of an electronic system with a thermal management system,

FIG. 12 illustrates an example embodiment of an electronic system with a thermal management system,

FIG. 13 illustrates an example embodiment of an electronic system with a thermal management system,

FIG. 14 illustrates an example embodiment of an electronic system with a thermal management system,

FIG. 15 illustrates an example embodiment of an electronic system with a thermal management system,

FIG. 16A illustrates an example embodiment of a thermal interface material layer,

FIG. 16B illustrates an example embodiment of a thermal interface material layer,

FIG. 16C illustrates an example embodiment of a thermal interface material layer,

FIG. 17A illustrates an example embodiment of an electronic system with a thermal management system,

FIG. 17B illustrates an example embodiment of an electronic system with a thermal management system,

FIG. 17C illustrates an example embodiment of an electronic system with a thermal management system,

FIG. 18A illustrates an example embodiment of an electronic system with a thermal management system,

FIG. 18B an example embodiment of an electronic system with a thermal management system,

FIG. 19 illustrates a process flow for detection of electronic system quality, and

FIG. 20 illustrates a block diagram of a process flow for the operation of an electronic system with a thermal management system.

### DETAILED DESCRIPTION OF THE INVENTION

In the following description, for the purposes of explanation, numerous specific details are set forth in order to provide a thorough understanding of the present invention. It will be apparent, however, that the present invention may be practiced without these specific details. In other instances, well-known structures and devices are shown in diagram form in order to avoid unnecessarily obscuring the present invention.

Embodiments are described herein according to the following outline:
1.0. Overview
2.0. System Overview
3.0. Performance Analysis
4.0. Functional Overview
5.0 Example Embodiments
6.0. Extensions and Alternatives

### 1.0. OVERVIEW

This overview presents a basic description of some aspects of possible embodiments of the present system. It should be noted that this overview is not an extensive or exhaustive summary of aspects of the possible embodiment. Moreover, it should be noted that this overview is not intended to be understood as identifying any particularly significant aspects or elements of the possible embodiment, nor as delineating any scope of the possible embodiment in particular, nor the invention in general. This overview merely presents some concepts that relate to the example possible embodiment in a condensed and simplified format and should be understood as merely a conceptual prelude to a more detailed description of example possible embodiments that follows below.

The thermal management system can monitor temperature and temperature differentials on a semiconductor die using an array of thermal diodes formed on the semiconductor die. The system for measuring these temperatures can be used to determine the quality and configuration of a thermal interface material layer on the semiconductor die used to distribute heat generated by the semiconductor die. The system can include two or more pairs of thermal diodes configured to measure the temperature of the die at specific locations on the die. By comparing the difference in temperatures between different diode pairs, variations in thermal measurement can be cancelled out and measurement accuracy can be significantly improved. The difference in junction temperature can be effectively used to detect spatial irregularities in the thermal interface material layer between the semiconductor die and a heat spreader or other radiating element. Such detection of spatial irregularities can be advantageously used to predict the likelihood of unacceptable spatial temperature differences on the die to ensure a target level of RAS. The structures and methods disclosed herein can be advantageously used during the manufacturing process (e.g., assembly and test), in a system environment (e.g., when the chip is mounted on a board), and during operation of the semiconductor device in the field (e.g., in a server or a rack of servers).

### 2.0. SYSTEM OVERVIEW

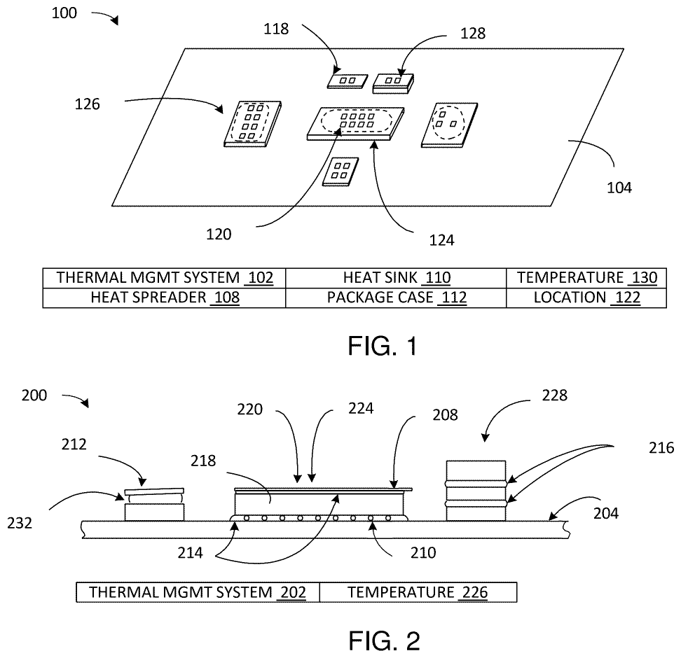

FIG. 1 depicts an example embodiment of an electronic system 100 with a thermal management system 102. The thermal management system 102 can include a semiconductor die 124 mounted on a mounting substrate 104. The semiconductor die 124 can be coupled to a heat transfer element such as a heat spreader 108, heat sink 110, package case 112, encapsulant material, or other similar thermal management components.

The electronic system 100 can include a thermal diode array 118 to measure the temperature 130 of different locations on the semiconductor die 124 during operation. The thermal diode array 118 can include thermal diodes 120 which can measure the temperature 130 at a location 122 of the diode. The thermal diodes 120 are electronic components that can be formed as part of the semiconductor die 124.

The thermal diode array 118 can have a variety of configurations. In some configurations, the thermal diode array 118 can be part of the circuitry implemented on the semiconductor die 124. The thermal diode array 118 can include a plurality of the thermal diodes 120 in different locations on the semiconductor die 124. The thermal diode array 118 can be configured to locate the thermal diodes 120 in one or more areas of the semiconductor die 124 where the temperature 130 is calculated to determine the condition and quality of the system at those locations.

The thermal management system 102 can include one or more semiconductor dies 124 and optionally one or more chiplets 126. The chiplet 126 is a semiconductor die 124 that can be configured to provide a dedicated functionality. The chiplets 126 are electrically coupled to the semiconductor die 124 and other on-board components and elements. For example, the chiplets 126 can be electrically coupled to the semiconductor die 124 and other components of the system. The chiplets 126 can also include thermal diodes 120 which can measure the temperature 130 at the location 122 of the diode on the chiplet 126.

In some embodiments, the system can include a plurality of chiplets 126 to provide additional functionality within the electronic system 100. The chiplets 126 can be configured as single layer components or multi-layer stacked components 128.

In other embodiments, the mounting substrate 104 can be a package base, a printed circuit board, a semiconductor package, a system on a chip base, an interposer, or other similar structure.

FIG. 2 depicts a side view of an example embodiment of an electronic system 200. In some embodiments, the thermal management system 202 can include a mounting substrate 204 having a semiconductor die 218. In some other embodiments, the thermal management system 202 can include the semiconductor die 218 attached to a mounting substrate 204. The semiconductor die 218 can be thermally coupled to a heat spreader 208 using a thermal interface material layer 214 (TIM layer 214). The heat spreader 208 is a thermally conductive structure used to dissipate or transfer heat. The heat spreader 208 can be a variety of structures including a heat sink, a plate or plating, a case, a cap, or other similar structures. In some embodiments, the TIM layer 214 can be formed between the semiconductor die 218 and the mounting substrate 204. For example, a thermal paste can be applied between the ball grid array balls 210 and the mounting substrate 204. In yet other embodiments, the TIM layer 214 can be formed between different chiplets 212 in a stack of the chiplets 212 components.

The TIM layer 214 can be a layer of thermally conductive material configured to facilitate the transfer of heat energy from areas of the semiconductor die 218 to the heat spreader 208. The thermal interface material 216 can be applied in a variety of ways. In some embodiments, the thermal interface material 216 can form a uniform layer that can evenly distribute heat. In other embodiments, the TIM layer 214 can be non-uniform resulting in an irregular thermal profile. The system and methods described herein can be used to detect an irregular thermal profile indicating the temperature differences across the semiconductor die 218. These methods and techniques can be advantageously used to detect the electronic system 200 having non-uniform TIM layer 214 that would result in reliability problems in normal operation (e.g., thermal breakdown and degradation).

The semiconductor die 218 and the chiplets 126 can be mounted on a mounting substrate 204. The mounting substrate 204 can be a printed circuit board, a semiconductor package, an interposer, or other similar structure.

The semiconductor die 218 can include a thermal diode array 224 of thermal diodes 220 that are used to measure a temperature 226 and the difference in temperature 226 in the thermal diode array 224.

The chiplets 126 can have a variety of configurations. For example, the chiplets 126 can be configured as single level or multiple level with different numbers of the chiplets 126 stacked on top of one another.

The chiplets 126 can include the thermal diode arrays 218 to measure the temperature 226 of the chiplets 126. In a multi-level configuration 228, the chiplets 126 on each level can include the thermal diode arrays 218 to provide temperature 226 measurement in the vertical dimension as well and in the two-dimensional directions.

The semiconductor die 218 and the chiplets 126 can include a heat spreader 208 structure at or near the top of the dies. In some embodiments, the heat spreader 208 can cover the single semiconductor die 218 or the chiplet 126. In some other embodiments, the heat spreader 208 can cover two or more elements such as the semiconductor die 218 and one or more chiplets 126, or two or more of the chiplets 126.

In some configurations, the TIM layer 214 can be non-uniform due to manufacturing issues. The heat spreader 208 can have a tilt angle 232 where one portion of the TIM layer 214 is thinner than other areas. This can be due to coining, or the irregular application of force when applying the heat spreader 208 elements. Irregular TIM layer 214 thickness can result in improper cooling of the components and can cause thermal damage to the components.

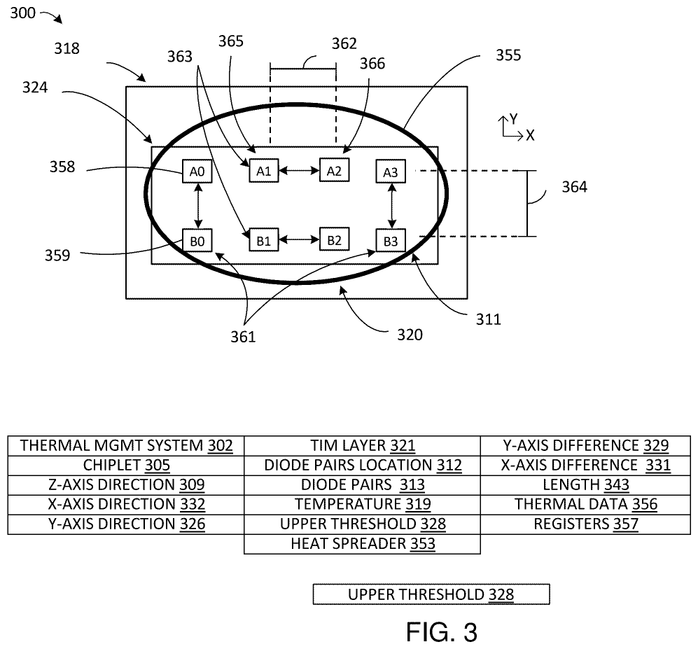

FIG. 3 depicts an example embodiment of an electronic system 300 with a thermal management system 302. The electronic system 300 can include a semiconductor die 324 mounted on a mounting substrate 304. The electronic system 300 can include a thermal diode array 318 for measuring temperature at different locations on the semiconductor die 324. In addition, the difference of the temperature measurement between two diodes can be used to measure thermal non-uniformity or hot spots in a particular region of the die.

The semiconductor die 324 is an active component that has electronic circuitry. The semiconductor die 324 includes the thermal diode array 318 having a plurality of thermal diodes 311. In some embodiments the thermal diodes 311 are formed as part of the semiconductor die 324. In other embodiments, the thermal diodes 311 can be formed on a different layer than the semiconductor die 324. For example, in a multi-component stack the thermal diodes 311 can be formed on one die and still be used to measure the temperature on another die. In addition, different layers can have different thermal diode arrays with different configurations. This can allow measuring the temperature and temperature difference in a z-axis direction 309 to allow for three-dimensional temperature information gathering.

The thermal diodes 311 can be configurated and positioned in a variety of ways. For example, the thermal diodes 311 can be an upper horizontal diode 358, a lower horizontal diode 359, a horizontal diode pair 361, a vertical diode pair 363, a left vertical diode 365, or a right vertical diode 366. The thermal diodes 311 can have a horizontal diode separation 362 and a vertical diode separation 364.

In some embodiments, the semiconductor die 324 can be a main component for implementing the desired functionality of the electronic system 300. In other embodiments, the semiconductor die 324 can be a chiplet 305, daughter module, coprocessor, or other active components.

The electronic system 300 can measure the temperature of the thermal diodes 311 in a variety of ways. In some embodiments, the system can read the temperature of each of the thermal diodes 311. To compensate for individual variance in the diodes, the system can calculate the temperature difference between each of the diodes in the thermal diode pair to get a temperature difference between each of the diodes and them compare the temperature difference with the temperature difference of an associated one of the diode pairs. Comparing the temperature difference of at least two of the diode pairs can show the variation of temperature differences over a portion of the semiconductor die 324. If the temperature difference of the diode pairs is above a threshold temperature difference, then the electronic system 300 can be determined to have an irregular configuration. Such devices can be flagged and removed as needed.

Using the temperature difference of the two diode pairs can provide a more robust and noise resistant measurement for determining system quality and functionality. In addition, using multiple temperature differences in different axes on the semiconductor die 324 can provide additional information about the thermal capacity and management of the electronic system 300. For example, measuring the temperature difference between the diode pairs in both the X-axis direction 332 and the Y-axis direction 326 can provide additional information about the type of potential failure modes such as the direction of the TIM layer 321 thickness variation due to coining or other problems.

The thermal diodes 311 can have a variety of configurations. In some embodiments, the thermal diodes 311 are arranged in a rectangular set of rows and columns on the semiconductor die 324. In other embodiments the thermal diodes 311 can be arranged in different shapes or patterns including triangular patterns, circular patterns, spiral patterns, and other regular and irregular patterns.

The diode pairs 313 can have a diode pair location 312. This can be the location 122 on the semiconductor die 324. The diode pair location 312 can have different configurations. In some embodiments, the diode pair location 312 can be the center between the two thermal diodes 311 of the diode pair 313, the location 122 of one of the diodes, the location 122 defined with an offset location 122, the location 122 defined relative to another diode pair 313, an enumerated location 122 identifier, or other location identifier.

The diode pairs 313 can have an X-axis direction diode separation and a Y-axis direction 326 diode separation. The separation distances can be uniform, or irregular based on engineering need. The temperature difference per unit distance can be another measure of the quality of the TIM layer 321 or the effect of other thermal irregularities.

The locations of the diode pairs 313 can be configured to measure a temperature 319 in a target region 320. The target region 320 can be an area where the TIM layer 321 should be uniform. It can be centered on a functional circuitry area of the semiconductor die 324, such as near a communication circuitry, processor circuitry, memory circuitry, hybrid circuitry, or other areas of particular concern.

Each of the thermal diodes 311 can be configured to measure the temperature at a particular location 122. The thermal diodes 311 can also be configured in pairs to determine the temperature difference between two locations. The temperature difference can also be known as the delta temperature, the delta junction temperature, temperature variance, temperature change, or other similar terms. The diode pairs can be used to measure the individual temperatures 319 of each of the thermal diodes 311 and then the difference between the two diodes can be calculated. Using the difference between the two diodes can result in a more robust thermal measurement. This can reduce the influence of individual diode readings, test fixture differences, environmental differences, batch differences, and any other differences.

In some embodiments, the temperature difference in the Y-axis direction 326 can be calculated by using the equation MAX (ABS(B1−A1), ABS(B2−A2)). Using the Maximum of the two deltas instead of averaging for the worst case can provide better results. In some configurations, an upper threshold 328 of a Y-axis difference 329 can be limited to 6.5 degrees Celsius. In other embodiments, other calculations can be used including average of a set of delta temperatures, mean value for multiple delta temperatures, a weighted average value, pre-calculated bands of values, or other similar methods.

In the X-axis direction 332, the left versus right temperature difference can be calculated using a formula of ABS(AVERAGE (A0, B0)−AVERAGE (A3, B3)). Using the absolute value of the difference between the average of the temperatures 319 of the individual thermal diodes 311 of the diode pair 313. In some configurations, the upper threshold 328 of the X-axis difference 331 can be limited to 7 degrees Celsius. Other calculations and thresholds can be used to determine and compare temperature differences between locations on the semiconductor die 324. In other embodiments, the X-axis direction 332 and Y-axis direction 326 can be swapped in the above calculations. In yet further embodiments, the diode pairs can be placed on the semiconductor die 324 to measure the temperature differences at specific sets of locations. In some embodiments, the electronic system 300 can include any number of the thermal diodes 311 configured to provide the desired thermal coverage areas. For example, the thermal diodes 311 can be configured as a rectangular array across any portion of the semiconductor die 324, as an array that is denser over specific circuitry areas, in a geometric pattern, or other similar configurations. In yet other embodiments, the calculation can include an average temperature difference over any number of the diode pairs. In other embodiments, the diode pairs can share one or more of the individual thermal diodes 311. For example, two of the diode pairs could be configured as A0/A1 and A0/B0 and share the temperature readings of A0 for calculating the temperature differences of these and other diode pairs.

In an illustrative example, the thermal diode array 318 can be configured as two rows of the thermal diodes 311 with four thermal diodes 311 in each row. The thermal diode array 318 can be formed in a target region 320 of the semiconductor die 324. The target region 320 can be a portion of the semiconductor die 324 where the heat generated during operation should be monitored. For example, in a configuration where a thermal interface material layer 321 is formed between the semiconductor die 324 and a heat spreader 353. The thermal interface material 355 is a thermally conductive material that will help transfer heat from the semiconductor die 324 to the heat spreader 353 to assist with cooling the semiconductor die 324. In alternative embodiments, more than two rows of diodes can be used, and each row can include any number of diodes. In addition, if certain areas of the die are likely to be more susceptible to thermal non-uniformity or hot spots (e.g., if the circuitry in certain areas of the die are likely to consume more power during normal operation), then some of the diodes can be placed in these areas instead of being placed in a regular pattern.

The thermal diode array 318 can be used to measure the temperature along a length 343 and width axes of the semiconductor die 324. In one configuration, the thermal diode array 318 can be a four by two array with an upper row A having four thermal diodes 311 and a lower row B having four thermal diodes 311. The diodes can be labelled A0, A1, A2, A3, B0, B1, B2, and B3. The four outermost thermal diodes 311, such as A0, B0, A3, B3, can be grouped into two vertical diode pairs, A0/B0 and A3/B3. The four inner thermal diodes 311, such as A1, A2, B1, and B2, can be grouped into two other horizontal diode pairs A1/A2 and B1/B2. These horizontal and vertical groups of the diode pairs can be used to determine the temperature and temperature difference along the length 343 (X-axis direction 332) and width (Y-axis direction 326) of the semiconductor die 324, respectively.

In some embodiments, two sets of the diode pairs can determine the variation in the temperature difference in different locations. For example, the A1/B1 diode pair 313 and the A2/B2 diode pair 313 can be used to measure the change in the temperature difference on the semiconductor die 324 in the Y-axis direction 326. In an illustrative example, if the temperature difference between A1 and B1 is 3 degrees Celsius and the temperature difference between A2 and B2 is 4 degrees Celsius, then the system can infer that there is max of 4 degrees Celsius temperature difference in the Y-axis direction 326. In some circumstances, this can indicate an irregularity in the associated thermal interface material layer 321 in the region of the two diode pairs.

In some embodiments, the temperature difference for the diode pair 313 can have an expected range between 0 and 6 degrees Celsius in either the X-axis direction 332 or the Y-axis direction 326. However, in some other embodiments, the maximum acceptable temperature difference can be lower or higher. In addition, the temperature difference can have a different operational threshold depending on the type of circuitry nearby. For example, more heat and potentially more temperature difference can be anticipated near processing circuitry, communication lanes, and other high power or high-density circuitry.

Similarly, the x-axis temperature difference variation can be measured by comparing the temperature difference between the A0/B0 diode pair 313 and the A3/B3 diode pair 313. For example, the A0/B0 diode pair 313 and the A3/B3 diode pair 313 can be used to measure the change in the temperature difference on the semiconductor die 324 in the X-axis direction 332. In an illustrative example, if the average temperature difference between A0 and B0 is 9 degrees Celsius higher than the average temperature difference between A3 and B3, then the system can infer that there is a change in the temperature difference between the two pairs of diodes in the X-axis direction 332. In some circumstances, this can indicate an irregularity in the associated thermal interface material layer 321 in the region of the two diode pairs.

In both of the above cases, the change in the temperature difference of the diode pairs could be due to irregularities in the thickness of the TIM layer 321, insufficient TIM coverage, bubbles or manufacturing flaws in the application of the thermal interface material 355, or other similar issues. Detecting the difference in the temperature difference between the various diode pairs can determine potential problems in the electronic system 300. Such components can be removed before shipping to customers.

During the manufacturing process, the thermal interface material layer 321 can be irregularly formed resulting in a non-uniform thermal interface material layer 321 that does not transfer heat to the heat spreader 353 in a uniform manner. In one example, the pressure applied to the heat spreader 353 can resulting in coining, which is a condition where more pressure is applied on one side of the heat spreader 353, thus resulting in a thinner thickness of the thermal interface material 355 where the application pressure was higher. Other potential irregularities can result from gaps or bubbles in the thermal interface material 355.

The thermal diode array 318 is a group of thermal diodes 311 that can be configured to measure the temperature and temperature distribution in a target region 320 on the semiconductor die 324. The target region 320 is an area where a thermal interface material 355 has been applied. The target region 320 can be evaluated to determine how much of the thermal interface material 355 fills the area beneath the target region 320. This can be expressed as a percentage of the target region 320 that is directly above the thermal interface material 355.

The temperature and temperature difference information, such as thermal data 356, can be retrieved from the thermal diodes 311 in a variety of ways. In some embodiments, the electronic system 300 can include control circuitry, such as a controller, that can monitor and read information from the thermal diodes 311. The temperature and temperature difference information can be stored in registers 357 local to the semiconductor die 324, on-board the electronic system 300, or in an external device. The information can include a single instance of the data or multiple instances of the data, such as over a period of time.

In some other embodiments, the thermal data 356 can be used to detect defect conditions at a single time and over time. This can allow the detection of manufacturing problems as well as longer term problems that may change over time. For example, checking the longer-term changes in the temperature differences of the diode pairs can indicate the development of on-going thermal problems. Tracking the thermal changes can be used to predict later operational problems and allow preventive changes as needed. The ability to perform longer term temperature difference monitoring both spatially and temporally on the electronic system 300 provides status information that can be used to predict and track system errors and other problems.

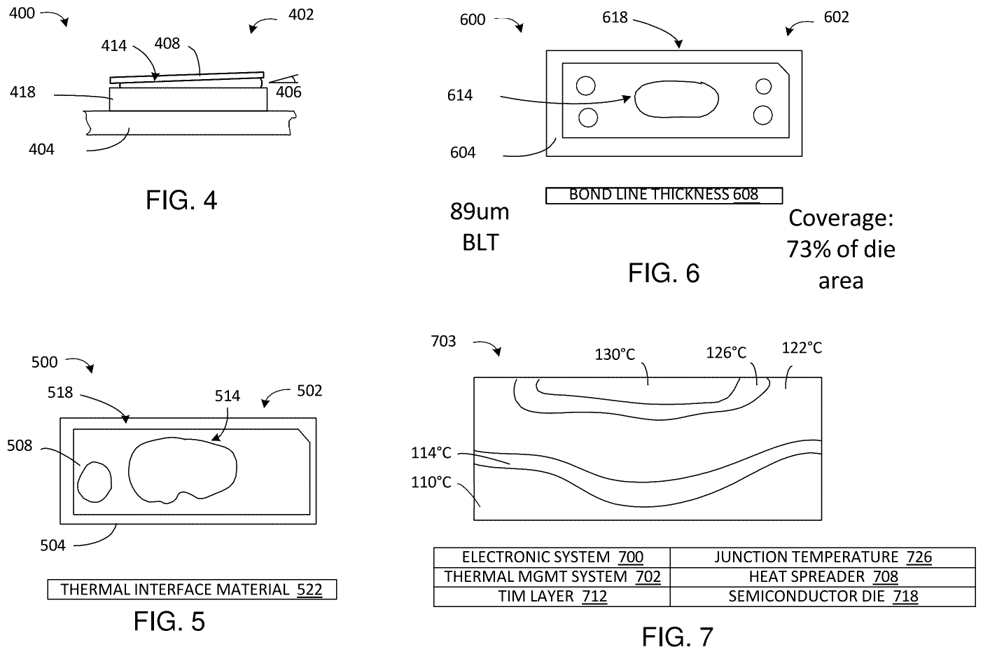

FIG. 4 depicts an example embodiment of an electronic system 400 with a thermal management system 402. The electronic system 400 can include a semiconductor die 418 with a thermal interface material layer 414, a mounting substrate 404, and a heat spreader 408.

The semiconductor die 418 can generate heat during operation. The heat spreader 408 can be an element such as a cover or cap formed from a heat conductive material configured to dissipate the heat from the semiconductor device.

The semiconductor die 418 and the heat spreader 408 can have the thermal interface material layer 414 between them to help with the transfer of heat from the semiconductor die 418 to the heat spreader 408. The thermal interface material layer 414 should be a uniform thickness for optimum heat flow.

However, the thermal interface material layer 414 can sometimes be incorrectly formed and exhibit a variety of problems. One such problem can be coining where the thermal interface material layer 414 has an irregular thickness, such as thicker on one side than another. This can result in one side of the heat spreader 408 forming a coining angle 406 where one side is closer to the semiconductor die 418 and transferring heat occurs in a non-uniform manner. Such errors in fabrication can result in functionality issues (e.g., complete or intermittent failure, incorrect operation, or other similar issues), reduced component lifetime, and higher power consumption.

FIG. 5 depicts an example embodiment of an electronic system 500 with a thermal management system 502. The electronic system 500 can include a semiconductor die 518 with a heat spreader 508 attached to a substrate 504. A thermal interface material layer 514 is formed by placing a thermal interface material 522 between the semiconductor die 518 and the heat spreader 508 and pressing the heat spreader 508 down to distribute the thermal interface material 522. The thermal interface material layer 514 can have a variety of shapes and thicknesses depending on the manufacturing process. Here, the thermal interface material layer 514 forms a roughly rounded oval or rectangle shape.

FIG. 6 depicts an example embodiment of an electronic system 600 with a thermal management system 602. The electronic system 600 can include a substrate 604 with a semiconductor die 618, a thermal interface material layer 614, and a heat spreader 608. The thermal interface material layer 614 can have a variety of shapes and thicknesses depending on the manufacturing process. Here, the thermal interface material layer 614 forms a roughly rounded oval or rounded rectangle shape covering approximately 73% of the die area. The electronic system 600 can have a bond line thickness 608 of 89 μm. The bond line thickness 608 is the thickness of the material used to attach a semiconductor die 618 to the substrate 604.

FIG. 7 depicts a thermal image of an example embodiment of an electronic system 700 with a thermal management system 702. The thermal image 703 shows the distribution of heat from a semiconductor die 718, a thermal interface material layer 712, and a heat spreader 708. In this example, the junction temperature 726 can reach 128.5 degrees Celsius during operation. Portions of the electronic system 700 can be +25 degrees Celsius above the nominal temperature of the electronic system 700. The pattern and distribution of heat can have a variety of causes including an irregular thickness of the thermal interface material layer, irregular TIM coverage, circuit layout, or other similar causes.

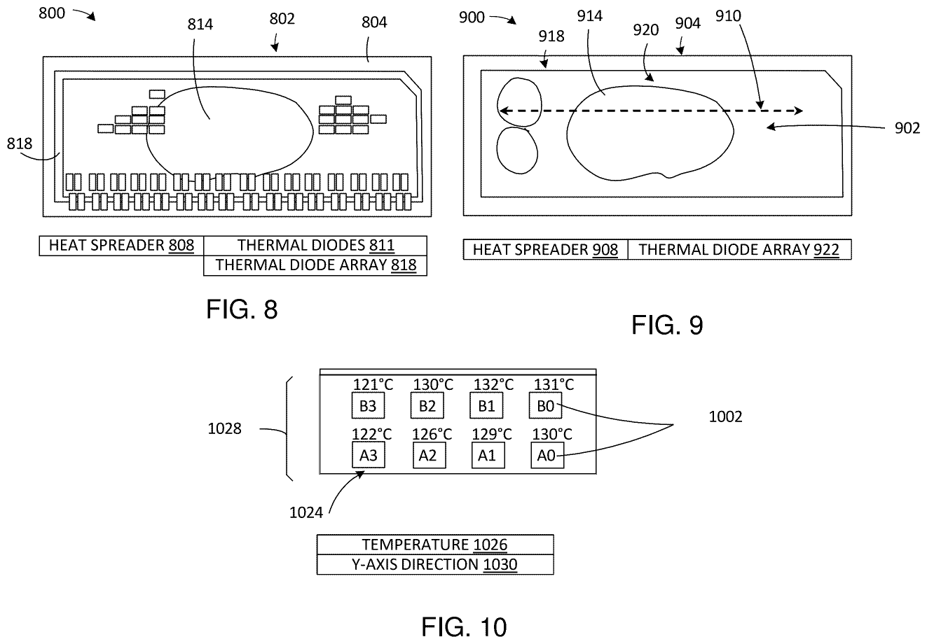

FIG. 8 depicts an example embodiment of an electronic system 800 with a thermal management system 802. The electronic system 800 can include a mounting substrate 804, a semiconductor die 818, a thermal interface material layer 814, and a heat spreader 808.

The electronic system 800 can also include a thermal diode array 822 having thermal diodes 811. The thermal diode array 822 can have a variety of layouts with different numbers of the thermal diodes 811. The electronic system 800 can also include capacitors, on-package de-coupling capacitors, power capacitors, and AC coupling capacitors for high-speed signals.

FIG. 9 depicts an example embodiment of an electronic system 900 with a thermal management system 902. The electronic system 900 can include a substrate 904, a semiconductor die 918, a thermal interface material layer 906, and a heat spreader 908.

The electronic system 900 can show a dashed line indicating a target region 920 where thermal measurements should be made using a thermal diode array 922. The target region 920 may indicate where thermally important circuitry resides on the semiconductor die 918. This can represent a region that may require a good quality thermal interface material layer 906 as shown by the rounded rectangle shape of the TIM layer 914. A dashed line 910 can indicate the cross-section line for bond line thickness (BLT) measurements.

FIG. 10 depicts an example embodiment of a thermal diode array 1028 for an electronic system 100 with a thermal management system 102. The thermal diode array 1028 can include eight thermal diodes 1002 A0, A1, A2, A3, B0, B1, B2, and B3. The thermal diode array 1028 can have thermal diodes 1002 arranged as four of the diode pairs configured as a horizontal diode pair 1024 and a right horizontal diode pair 1024—B3/B0 and A3/A0, and two vertical diode pairs—A1/A2 and B1/B2.

In an illustrative example, the thermal diode array 1028 can be used to calculate the temperature differences for each of the diode pairs. An average temperature 226 of B3/A3 diode pair 1024 shows 121.5 degree Celsius, and average temperature 1026 of B0/A0 diode pair 1024 shows 130.5 degree Celsius. The temperature difference on X-axis is 9 degrees Celsius, which is an indication of TIM uniformity issue between left and right side of the semiconductor device.

The A1/B1 diode pairs shows a temperature difference of 3 degrees Celsius and the A2/B2 diode pair 1024 shows a temperature difference of 4 degrees Celsius. Thus, the difference between the two innermost vertical diode pairs shows a maximum difference of 4 degree Celsius. This difference shows there is an underlying thermal irregularity in the Y-axis direction 1030. This could indicate insufficient TIM coverage at the location of the upper region of the semiconductor device.

In some embodiments, the magnitude of the difference between the temperature difference of the two diode pairs can be compared to a predetermined threshold value to determine if a significant irregularity is present. For example, if the difference between the readings from the two diode pairs is below 2 degrees Celsius, then the component can be deemed acceptable, but if the readings from the two diode pairs is 2 degrees Celsius or greater, then the component can be deemed unacceptable and rejected. The threshold value can be selected based on desired RAS criteria, e.g., a lower threshold value can be used to select parts having a higher RAS, and a higher threshold value can be used to select parts having a lower RAS. In certain embodiments multiple predetermined threshold values can be used to group semiconductor devices into two or more groups having similar estimated RAS characteristics (e.g., multiple bins, etc.), wherein devices in a particular group can be used in specific applications having the estimated RAS characteristics.

In yet other embodiments, the pairing of the thermal diodes 1002 can be different. For example, the temperature difference can be calculated for one of the diode pairs that are further apart, such as B0/A3, to get the temperature difference over a larger distance. Any two of the thermal diodes 1002 can be used to form one of the diode pairs. The distance between the thermal diode 120 of one of the diode pairs can be regular or irregular.

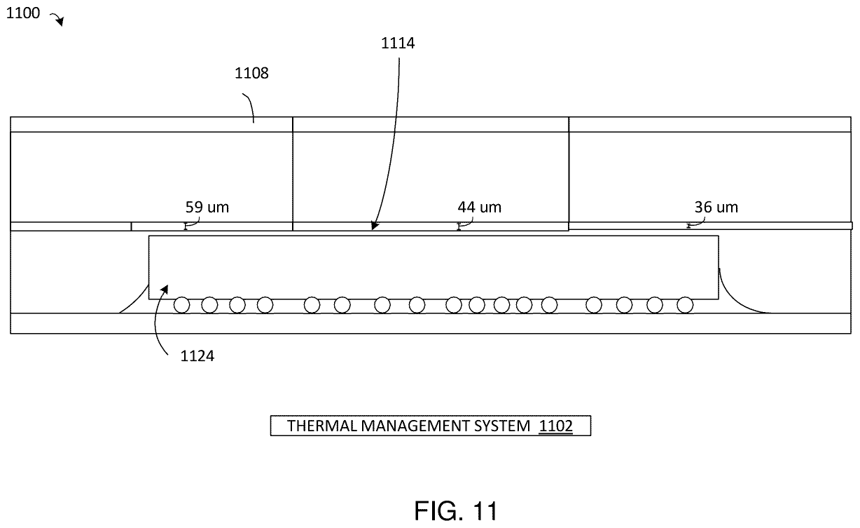

FIG. 11 depicts an example embodiment of a thermal interface material layer 1114 of an electronic system 1100 with a thermal management system 1102. The electronic system 1100 can include a semiconductor die 1124, a thermal interface material layer 1114, and a heat spreader 1108. The TIM layer 1114 is shown with different thicknesses. The left thickness is 59 μm, the middle thickness is 44 μm, and the right thickness is 36 um. This gradual decrease in the thickness of the thermal interface material layer 1114 can indicate the effect of coining. If the gradual decrease in thickness results in a significant temperature difference, then the component can be rejected.

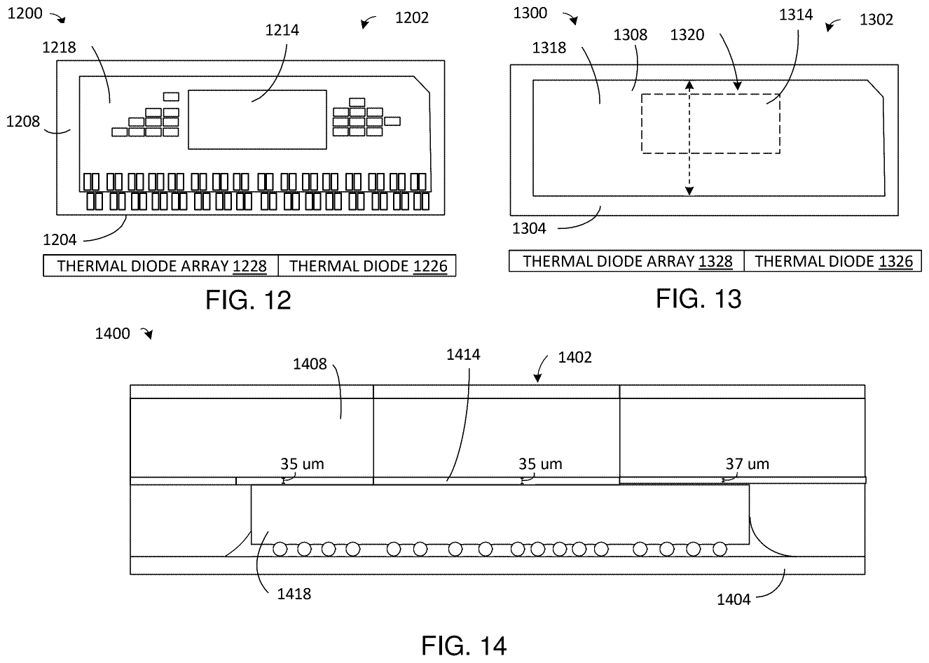

FIG. 12 depicts an example embodiment of an electronic system 1200 with a thermal management system 1202. The electronic system 1200 can include a substrate 1204, a semiconductor die 1218, a thermal interface material layer 1214, and a heat spreader 1208.

The electronic system 1200 can also show a thermal diode array 1228 having thermal diodes 1226. The thermal diode array 1228 can have a variety of layouts with different numbers of the thermal diodes 1226.

FIG. 13 depicts an example embodiment of an electronic system 1300 with a thermal management system 1302. The electronic system 1300 can have a variety of configurations. The electronic system 1300 can include a substrate 1304, a semiconductor die 1318, a thermal interface material layer 1314, and a heat spreader 1308. The electronic system 1300 can include other configurations as well.

The electronic system 1300 can show a dashed vertical line 1316 indicating a target region 1320 where thermal measurements should be made using the thermal diode array 1328. The target region 1320 may indicate where thermally important circuitry resides on the semiconductor die 1318. This can represent a region that may require a good quality thermal interface material layer 1314 as shown by the rounded rectangle shape of the TIM layer 1314. The dashed line can indicate where the cross section is taken in the destructive physical failure analysis.

FIG. 14 depicts an example embodiment of an electronic system 1400 with a thermal management system 1402. The electronic system 1400 can include a semiconductor die 1418, the thermal interface material layer 1414, a heat spreader 1408, and a mounting substrate 1404. The TIM layer 1414 is shown with only minor differences in thicknesses. The left thickness is 35 um, the middle thickness is 35 um, and the right thickness is 37 um. This minor decrease in the thickness of the thermal interface material layer 1414 can indicate the small effect of coining, but the small degree of change can indicate that the temperature difference between the two areas is low, and the component can be acceptable.

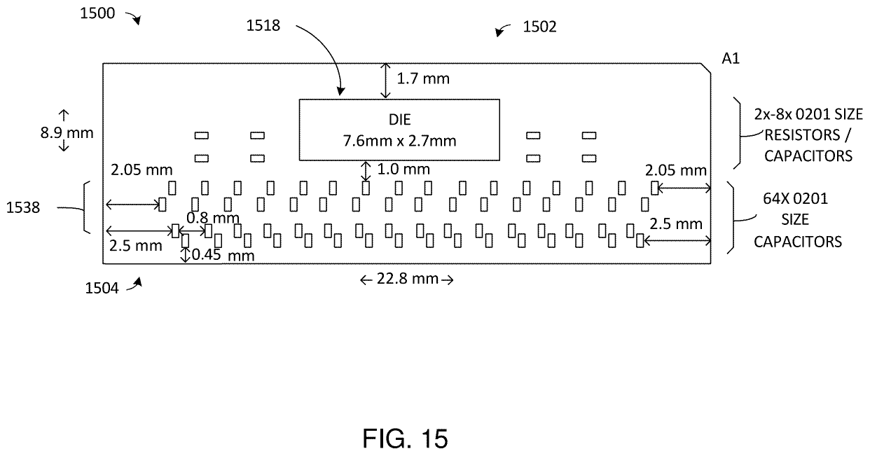

FIG. 15 depicts an example embodiment of an electronic system 1500 with a thermal management system 1502. The electronic system 1500 can include a semiconductor die 1518 attached to a mounting substrate 1504. The mounting substrate 1504 can include other active and passive components 1538.

In some embodiments, the semiconductor die 1518 can have a size of 7.7 mm by 2.7 mm. The semiconductor die 1518 can be offset from the top side of the mounting substrate 1504 by 1.7 mm. The mounting substrate 1504 can have a size of 8.9 mm by 22.8 mm.

The electronic system 1500 can include 2×-8×0201 size resistors/capacitors. The electronic system 1500 can include 64×0201 size capacitors in a double row offset arrangement. The capacitors can be offset from the semiconductor die 1518 by 1.0 mm. The capacitors can be offset from the left side by 2.05 mm and 2.5 mm. The rows can be offset from adjacent rows by 0.65 mm. The bottom most row of capacitors can be 0.45 mm from the bottom side of the mounting substrate 1504.

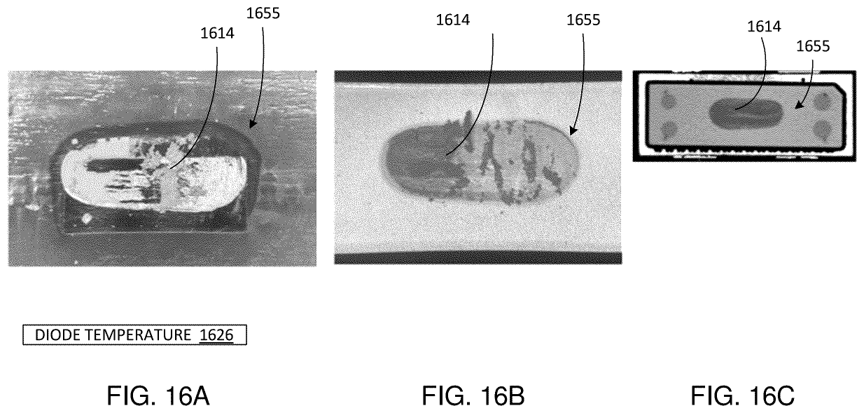

FIGS. 16A, 16B, and 16C show example embodiments of a thermal interface material layer 1614. The thermal interface material layer 1614 can have a variety of different flaws.

FIG. 16A depicts an example embodiment of a thermal interface material layer 1614. The thermal interface material layer 1614 can have various gaps and holes. Thermal interface material 1655 is only covering portion of the die while leaving one side not covered. The side covered with TIM material will have a lower diode temperature 1626 vs the side without TIM material.

FIG. 16B depicts an example embodiment of a thermal interface material layer 1614. The thermal interface material layer 1614 can have various gaps and holes. Thermal interface material 1655 is only covering portion of the die while leaving one side not covered. This can result in insufficient TIM coverage over the die on the bottom side of the package.

FIG. 16C depicts an example embodiment of a thermal interface material layer 1614. The thermal interface material layer 1614 can have various gaps and holes. Thermal interface material 1655 is only covering portion of the die while leaving one side not covered.

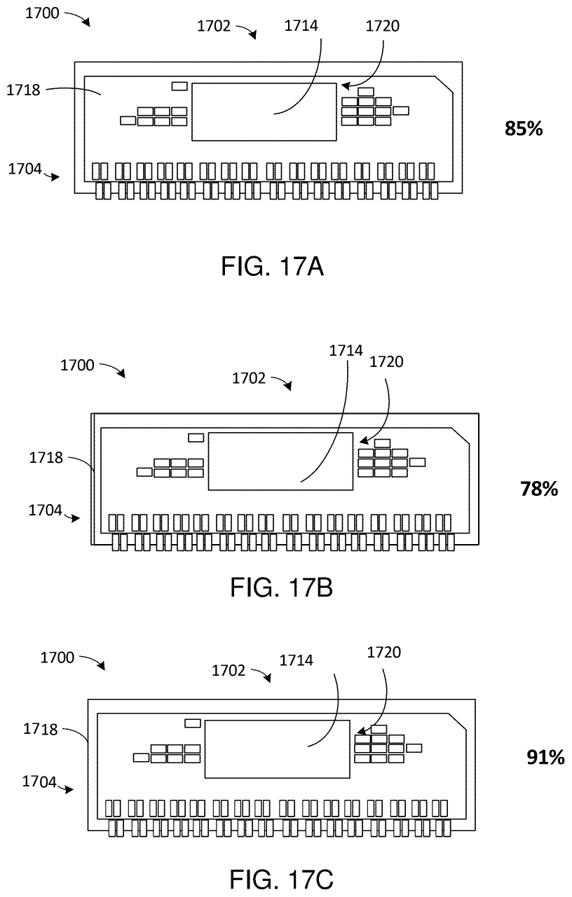

FIGS. 17A, 17B, and 17C show different embodiments an electronic system 1700 with a thermal management system 1702. The electronic system 1700 can include a semiconductor die 1718 and other passive components 1738 attached to a substrate 1704.

FIG. 17A depicts an example embodiment of an electronic system 1700 with a thermal management system 1702. The electronic system 1700 can include rows of resistors and capacitors near the sides of the semiconductor die 1718 and rows of capacitors along the bottom side of the substrate 1704. The system can include a target region 1720 that can overlap a portion of the thermal interface material layer 1714. In some cases, the target region 1720 can overlap by 85%.

FIG. 17B depicts an example embodiment of an electronic system 1700 with a thermal management system 1702. The electronic system 1700 can include rows of resistors and capacitors near the sides of the semiconductor die 1718 and rows of capacitors along the bottom side of the substrate 1704. The system can include a target region 1720 that can overlap a portion of the thermal interface material layer 1714. In some cases, the target region 1720 can overlap by 78%.

FIG. 17C depicts an example embodiment of an electronic system 1700 with a thermal management system 1702. The electronic system 1700 can include rows of resistors and capacitors near the sides of the semiconductor die 1718 and rows of capacitors along the bottom side of the substrate 1704. The system can include a target region 1720 that can overlap a portion of the thermal interface material layer 1714. In some cases, the target region 1720 can overlap by 91%.

### 3.0. PERFORMANCE ANALYSIS

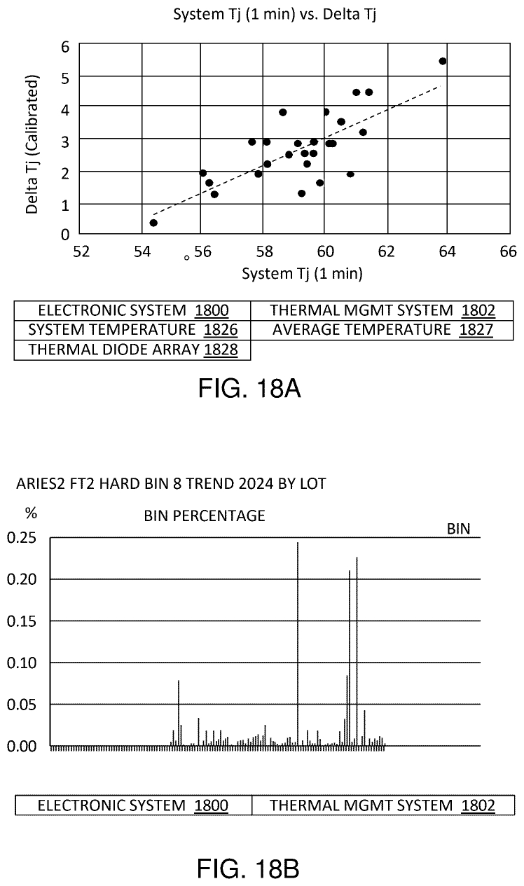

FIGS. 18A and 18B depict example embodiments of data from an electronic system 1800 with a thermal management system 1802. The data can be shown in graphical format to illustrate properties of the electronic system 1800.

FIG. 18A depicts an example embodiment of an electronic system 1800 with a thermal management system 1802. The chart shows the correlations between a system temperature 1826 and the temperature difference of a plurality of diode pairs.

The system temperature 1826 can be calculated in a variety of ways. In some embodiments, the system temperature 1826 can be the average temperature 1827 of a portion of a thermal diode array 1828. The portion can include the entire thermal diode array 1828.

FIG. 18B depicts an example embodiment of an electronic system 1800 with a thermal management system 1802. The chart shows the SEMI HB8 quality measurement for different embodiments of the electronic system 1800. The hard bin 8 (HB8) is the bin assigned for thermal rejecting in the automated test equipment (ATE) when the temperature difference (delta Tj) exceeds a pre-defined threshold. This information can provide information about the TIM uniformity of the components.

### 4.0. FUNCTIONAL OVERVIEW

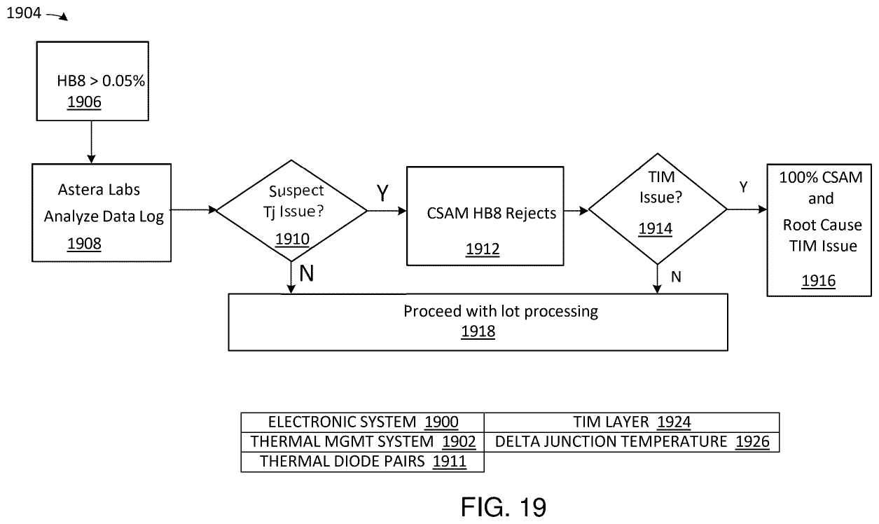

FIG. 19 depicts a process flow for detection of electronic system 1900 quality. The SEMI HB8 quality measure can be calculated for the electronic system 1900 during manufacturing. The process flow 1904 has a variety of configurations. In one embodiment, the process flow 1904 can have a first step 1906, a second step 1908, a third step 1910, a further step 1912, a fifth step 1914, a sixth step 1916, and a seventh step 1918.

The first step can check if the HB8 is above 0.05%. This can be performed by analyzing the data log or implementing statistical bin limit during final test. The next step can check if a delta junction temperature 1926 of one of the thermal diode pairs 1911 is an issue. If not, then it is recommended to proceed with lot processing for manufacturing. If it is an issue, then it is recommended to use confocal scanning acoustic microscopy (CSAM) to evaluate the electronic system 1900 components that may have been flagged as rejected to evaluate the thermal interface material layer 1924. The next process step can check if there is a TIM issue. If not, then proceed with the lot processing. If so, then proceed with complete CSAM for the entire assembly lot and determine the root cause of the TIM issue.

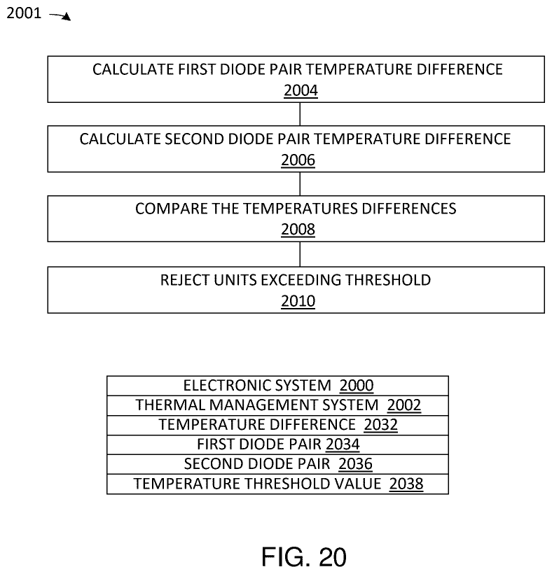

FIG. 20 depicts an operating process flow 2001 for the operation of an electronic system 2000 with a thermal management system 2002. The operating process flow 2001 can describe the steps and process for operating the electronic system 2000.

The operating process flow 2001 can include a variety of operations. In an illustrative embodiment, the operating process flow 2001 can include a calculate first diode pair temperature difference step 2004, a calculate second diode pair temperature difference step 2006, a compare temperature differences step 2008, and a rejection step 2010.

In the calculate first diode pair temperature difference step 2004, the system can calculate the temperature difference between the two thermal diodes of a first diode pair 2034. Calculating a temperature difference 2032 between the two thermal diodes can provide a better metric by reducing the impact of individual variations in the thermal diodes.

In the calculate second diode pair temperature difference step 2006, the system can calculate the temperature difference 2032 between the two thermal diodes of a second diode pair 2036. Again, calculating the temperature difference 2032 between the two thermal diodes can provide a better metric by reducing the impact of individual variations in the thermal diodes.

In the compare the temperature differences step 2008, the system can compare the first pair temperature difference and the second pair temperature difference against a threshold and determine if the temperature differences 2032 is large enough to indicate a problem with the semiconductor die. This can be done by comparing the two temperature differences to a temperature threshold value 2038. The temperature threshold value 2038 can be a predetermined value and can be linked to a target region on the semiconductor die. This can allow the use of a temperature profile for certain portions of the semiconductor die. For example, the target region could be configured as a processing or communication circuitry on the semiconductor die. Monitoring the difference in the temperature of the two separate diode pairs in a specific target region can provide finer grained control and early detection of potential problems.

Comparing the diode pair temperature differences can be used to calculate a quality value that can determine whether the thermal performance of the semiconductor die is enough for the device to be rejected. For example, if the temperature difference 2032 of the two pairs is larger than the targeted threshold value, then the quality value can indicate that the component has failed and should be rejected.

In the reject units exceeding threshold step 2010, the quality value can be used by a testing or manufacturing system to reject the unit that has a failing quality value. In some embodiments, the electronic system can send the quality value to the testing system and the testing system can transfer the system into a reject bin or otherwise indicate that the failed component cannot be used. Units with an adequate quality value can be transferred into a successful devices bin or storage unit.

After the decision to reject or accept the unit, the control flow can pass back to the first step in the process.

### 5.0 EXAMPLE EMBODIMENTS

Examples of some embodiments are represented, without limitation, in the following clauses and use cases:

According to an embodiment, a method of operation of an electronic system comprises calculating a first temperature difference between two thermal diodes of a first diode pair of a thermal diode array positioned within a target region of a semiconductor die attached to a mounting substrate with a thermal interface material layer directly on the semiconductor die and between the semiconductor die and the mounting substrate, calculating a second temperature difference between two thermal diodes of a second diode pair within the target region, calculating a quality parameter of the semiconductor die based on the first temperature difference within a threshold temperature difference of the second temperature difference, and rejecting the semiconductor die based on comparing the quality parameter to a quality threshold value.

In an embodiment, the method wherein calculating the first temperature difference includes calculating the first temperature difference of the first diode pair configured as a first vertical diode pair with a first vertical diode separation distance in a y-direction, and calculating the second temperature difference of the second diode pair configured as a second vertical diode pair with a second vertical diode separation distance in the y-direction.

In an embodiment, the method wherein calculating the first temperature difference includes calculating the first temperature difference of the first diode pair configured as a first horizontal diode pair with a first horizontal diode separation distance in a x-direction, and calculating the second temperature difference of the second diode pair configured as a second horizontal diode pair with a second horizontal diode separation distance in the x-direction.

In an embodiment, the method wherein calculating the quality parameter includes calculating a third temperature difference between two thermal diodes of a third pair of thermal diodes within the target region, calculating a fourth temperature difference between two thermal diodes of a fourth pair of thermal diodes within the target region, and calculating the quality parameter of the semiconductor die based on the first temperature difference within the threshold temperature difference from the second temperature difference, the third temperature difference, and the fourth temperature difference, the quality parameter indicating failure if one of the temperature differences is not within the threshold temperature difference.

In an embodiment, the method wherein attaching the semiconductor die includes configuring the thermal diode array in a rectangular pattern, a circular pattern, a spiral pattern, or a random pattern.

In an embodiment, the method wherein attaching the semiconductor die includes configuring the thermal diode array in a first target region and a second target region.

In an embodiment, the method wherein attaching the semiconductor die includes positioning the thermal diode array within the target region on the semiconductor die and the threshold temperature configured based on the target region.

In an embodiment, the method wherein forming the thermal interface material layer includes forming the thermal interface material layer between a top side of the semiconductor die and a thermal spreader attached on the top side of the semiconductor die.

In an embodiment, the method wherein forming the thermal interface material layer includes forming the thermal interface material layer between the semiconductor die and the substrate.

In an embodiment, the method wherein attaching the semiconductor die includes calculating a third temperature difference between another two thermal diodes of a third diode pair in a second thermal diode array on a chiplet attached to the mounting substrate, the second thermal diode array within a second target region of the chiplet, and the chiplet directly on the mounting substrate with another thermal interface material layer directly on the chiplet and between the chiplet and the mounting substrate, calculating a fourth temperature difference between two thermal diodes of a fourth diode pair within the second target region, calculating a second quality parameter based on the third temperature difference within a second threshold temperature difference of the fourth temperature difference, and rejecting the chiplet based on comparing the second quality parameter to a second quality threshold value.

An electronic system comprises a mounting substrate, a semiconductor die attached to a mounting substrate, the semiconductor die having a thermal diode array within a target region of the semiconductor die, the thermal diode array having a first pair of thermal diodes and a second pair of thermal diodes, and a thermal interface material layer directly on the semiconductor die.

In an embodiment, the system wherein the first diode pair is configured as a first vertical diode pair with a first vertical diode separation distance in a y-direction, and the second diode pair is configured as a second vertical diode pair with a second vertical diode separation distance in the y-direction.

In an embodiment, the system wherein the first diode pair is configured as a first horizontal diode pair with a first horizontal diode separation distance in a x-direction, and the second diode pair is configured as a second horizontal diode pair with a second horizontal diode separation distance in the x-direction.

In an embodiment, the system further comprises a third pair of thermal diodes configured to calculate a third temperature difference between two thermal diodes of the third pair of thermal diodes, and a fourth pair of thermal diodes configured to calculate a fourth temperature difference between two thermal diodes of the fourth pair of thermal diodes.

In an embodiment, the system wherein the thermal diode array is configured in a rectangular pattern, a circular pattern, a spiral pattern, or a random pattern.

In an embodiment, the system wherein the thermal diode array is configured to have a first target region and a second target region on the semiconductor die.

The system as claimed in claim wherein the thermal diode array is formed within the target region on the semiconductor die and the threshold temperature configured based on the target region.

In an embodiment, the system wherein the thermal interface material layer is between a top side of the semiconductor die and a thermal spreader.

In an embodiment, the system wherein the thermal interface material layer is between the semiconductor die and the substrate.

In an embodiment, the system further comprises a chiplet attached to the mounting substrate, the chiplet having a second thermal diode array within a second target region of the chiplet, the second thermal diode array having a third pair of thermal diodes and a fourth pair of thermal diodes, and another thermal interface material layer directly on the chiplet.

### 6.0 EXTENSIONS AND ALTERNATIVES

As used herein, the terms “first,” “second,” “certain,” and “particular” are used as naming conventions to distinguish queries, plans, representations, steps, objects, devices, or other items from each other, so that these items may be referenced after they have been introduced. Unless otherwise specified herein, the use of these terms does not imply an ordering, timing, or any other characteristic of the referenced items.

In the drawings, the various components are depicted as being communicatively coupled to various other components by arrows. These arrows illustrate only certain examples of information flows between the components. Neither the direction of the arrows nor the lack of arrow lines between certain components should be interpreted as indicating the existence or absence of communication between the certain components themselves. Indeed, each component may feature a suitable communication interface by which the component may become communicatively coupled to other components as needed to accomplish any of the functions described herein.

In the foregoing specification, embodiments of the inventive subject matter have been described with reference to numerous specific details that may vary from implementation to implementation. Thus, the sole and exclusive indicator of what is the inventive subject matter, and is intended to be the inventive subject matter, is the set of claims that issue from this application, in the specific form in which such claims issue, including any subsequent correction. In this regard, although specific claim dependencies are set out in the claims of this application, it is to be noted that the features of the dependent claims of this application may be combined as appropriate with the features of other dependent claims and with the features of the independent claims of this application, and not merely according to the specific dependencies recited in the set of claims. Moreover, although separate embodiments are discussed herein, any combination of embodiments and/or partial embodiments discussed herein may be combined to form further embodiments.

Any definitions expressly set forth herein for terms contained in such claims shall govern the meaning of such terms as used in the claims. Hence, no limitation, element, property, feature, advantage or attribute that is not expressly recited in a claim should limit the scope of such claim in any way. The specification and drawings are, accordingly, to be regarded in an illustrative rather than a restrictive sense.

1. A method of operation of an electronic system comprising:
calculating a first temperature difference between two thermal diodes of a first diode pair of a thermal diode array positioned within a target region of a semiconductor die attached to a mounting substrate with a thermal interface material layer directly on the semiconductor die and between the semiconductor die and the mounting substrate;
calculating a second temperature difference between two thermal diodes of a second diode pair within the target region;
calculating a quality parameter of the semiconductor die based on the first temperature difference within a threshold temperature difference of the second temperature difference; and
rejecting the semiconductor die based on comparing the quality parameter to a quality threshold value.

2. The method as claimed in claim 1, wherein calculating the first temperature difference includes:
calculating the first temperature difference of the first diode pair configured as a first vertical diode pair with a first vertical diode separation distance in a y-direction; and
calculating the second temperature difference of the second diode pair configured as a second vertical diode pair with a second vertical diode separation distance in the y-direction.

3. The method as claimed in claim 1, wherein calculating the first temperature difference includes:
calculating the first temperature difference of the first diode pair configured as a first horizontal diode pair with a first horizontal diode separation distance in a x-direction; and
calculating the second temperature difference of the second diode pair configured as a second horizontal diode pair with a second horizontal diode separation distance in the x-direction.

4. The method as claimed in claim 1, wherein calculating the quality parameter includes:
calculating a third temperature difference between two thermal diodes of a third pair of thermal diodes within the target region;
calculating a fourth temperature difference between two thermal diodes of a fourth pair of thermal diodes within the target region; and
calculating the quality parameter of the semiconductor die based on the first temperature difference within the threshold temperature difference from the second temperature difference, the third temperature difference, and the fourth temperature difference, the quality parameter indicating failure if one of the temperature differences is not within the threshold temperature difference.

5. The method as claimed in claim 1, wherein attaching the semiconductor die includes configuring the thermal diode array in a rectangular pattern, a circular pattern, a spiral pattern, or a random pattern.

6. The method as claimed in claim 1, wherein attaching the semiconductor die includes configuring the thermal diode array in a first target region and a second target region.

7. The method as claimed in claim 1, wherein attaching the semiconductor die includes positioning the thermal diode array within the target region on the semiconductor die and the threshold temperature configured based on the target region.

8. The method as claimed in claim 1, wherein forming the thermal interface material layer includes forming the thermal interface material layer between a top side of the semiconductor die and a thermal spreader attached on the top side of the semiconductor die.

9. The method as claimed in claim 1, wherein forming the thermal interface material layer includes forming the thermal interface material layer between the semiconductor die and the substrate.

10. The method as claimed in claim 1, wherein attaching the semiconductor die includes:
calculating a third temperature difference between another two thermal diodes of a third diode pair in a second thermal diode array on a chiplet attached to the mounting substrate, the second thermal diode array within a second target region of the chiplet, and the chiplet directly on the mounting substrate with another thermal interface material layer directly on the chiplet and between the chiplet and the mounting substrate;
calculating a fourth temperature difference between two thermal diodes of a fourth diode pair within the second target region;
calculating a second quality parameter based on the third temperature difference within a second threshold temperature difference of the fourth temperature difference; and
rejecting the chiplet based on comparing the second quality parameter to a second quality threshold value.

11. An electronic system comprising:
a mounting substrate;
a semiconductor die attached to a mounting substrate, the semiconductor die having a thermal diode array within a target region of the semiconductor die, the thermal diode array having a first pair of thermal diodes and a second pair of thermal diodes; and
a thermal interface material layer directly on the semiconductor die.

12. The system as claimed in claim 11, wherein:
the first diode pair is configured as a first vertical diode pair with a first vertical diode separation distance in a y-direction; and
the second diode pair is configured as a second vertical diode pair with a second vertical diode separation distance in the y-direction.

13. The system as claimed in claim 11, wherein:
the first diode pair is configured as a first horizontal diode pair with a first horizontal diode separation distance in a x-direction; and
the second diode pair is configured as a second horizontal diode pair with a second horizontal diode separation distance in the x-direction.

14. The system as claimed in claim 11, further comprising:
a third pair of thermal diodes configured to calculate a third temperature difference between two thermal diodes of the third pair of thermal diodes; and
a fourth pair of thermal diodes configured to calculate a fourth temperature difference between two thermal diodes of the fourth pair of thermal diodes.

15. The system as claimed in claim 11, wherein the thermal diode array is configured in a rectangular pattern, a circular pattern, a spiral pattern, or a random pattern.

16. The system as claimed in claim 11, wherein the thermal diode array is configured to have a first target region and a second target region on the semiconductor die.

17. The system as claimed in claim 11 wherein the thermal diode array is formed within the target region on the semiconductor die and the threshold temperature configured based on the target region.

18. The system as claimed in claim 11, wherein the thermal interface material layer is between a top side of the semiconductor die and a thermal spreader.

19. The system as claimed in claim 11, wherein the thermal interface material layer is between the semiconductor die and the substrate.

20. The system as claimed in claim 11, further comprising:
a chiplet attached to the mounting substrate, the chiplet having a second thermal diode array within a second target region of the chiplet, the second thermal diode array having a third pair of thermal diodes and a fourth pair of thermal diodes; and
another thermal interface material layer directly on the chiplet.
